(19) United States
(12) Patent Application Publication
(10) Pub. No.: US 2022/0293401 A1
(43) Pub. Date: Sep. 15, 2022

(54) SEMICONDUCTOR MANUFACTURING APPARATUS AND SEMICONDUCTOR MANUFACTURING METHOD

(71) Applicant: Kioxia Corporation, Tokyo (JP)

(72) Inventor: Daichi KAWASAKI, Yokkaichi Mie (JP)

(73) Assignee: Kioxia Corporation, Tokyo (JP)

(21) Appl. No.: 17/409,514

(22) Filed: Aug. 23, 2021

(30) Foreign Application Priority Data
Mar. 15, 2021 (JP) 2021-041578

(51) Int. Cl. H01J 37/32; H01L 21/677; H01L 21/687; B08B 7/00; B08B 13/00; B25J 18/00; B65G 47/90

(52) U.S. Cl. CPC H01J 37/32862; H01L 21/67742; H01L 21/68707; B08B 7/0035; B08B 13/00; B25J 18/00; B65G 47/90; H01J 2237/335

(57) ABSTRACT

A semiconductor manufacturing apparatus includes a transfer device that includes a transfer blade whose mounting area on which a wafer is mounted is defined on a front surface and a transfer arm adjusting a position of the transfer blade, and a processing chamber that accommodates the transfer blade and is for removing foreign matter adhering to the mounting area.

### CROSS-REFERENCE TO RELATED APPLICATION

This application is based upon and claims the benefit of priority from Japanese Patent Application No. 2021-041578, filed Mar. 15, 2021, the entire contents of which are incorporated herein by reference.

### FIELD

Embodiments described herein relate generally to a semiconductor manufacturing apparatus and a semiconductor manufacturing method used in a manufacturing method for forming a semiconductor device on a wafer.

### BACKGROUND

The semiconductor device is formed on the wafer by a series of manufacturing processes. In order to execute the manufacturing processes in a plurality of chambers, respectively, a transfer device transfers the wafer between the chambers. In this case, the wafer is mounted on a predetermined mounting area of the transfer device.

### DESCRIPTION OF THE DRAWINGS

FIG. 1 is a schematic diagram illustrating a configuration of a semiconductor manufacturing apparatus according to a first embodiment.

FIG. 2 is a schematic diagram for illustrating a wafer transfer method in a processing chamber (first view).

FIG. 3 is a schematic diagram for illustrating the wafer transfer method in the processing chamber (second view).

FIG. 4A is a schematic diagram for illustrating a method of closing a shutter in the processing chamber (first view).

FIG. 4B is a schematic diagram for illustrating the method of closing the shutter in the processing chamber (second view).

FIG. 5A is a schematic diagram for illustrating the method of closing the shutter in the processing chamber (third view).

FIG. 5B is a schematic diagram for illustrating the method of closing the shutter in the processing chamber (fourth view).

FIG. 6A is a schematic diagram for illustrating the method of closing the shutter in the processing chamber (fifth view).

FIG. 6B is a schematic diagram for illustrating the method of closing the shutter in the processing chamber (sixth view).

FIG. 7 is a schematic view illustrating a configuration of a processing chamber of the semiconductor manufacturing apparatus according to the first embodiment.

FIG. 8A is a schematic cross-sectional view illustrating an example of a foreign matter generation process (first view).

FIG. 8B is a schematic cross-sectional view illustrating the example of the foreign matter generation process (second view).

FIG. 8C is a schematic cross-sectional view illustrating the example of the foreign matter generation process (third view).

FIG. 9 is a flowchart for illustrating a semiconductor manufacturing method according to the first embodiment.

FIG. 10 is a schematic view illustrating another configuration of the semiconductor manufacturing apparatus according to the first embodiment.

FIG. 11 is a schematic diagram illustrating a configuration of a semiconductor manufacturing apparatus according to modification of the first embodiment.

FIG. 12A is a schematic view illustrating an example of a method of connecting a transfer blade and a transfer arm of the semiconductor manufacturing apparatus according to the modification of the first embodiment (first view).

FIG. 12B is a schematic view illustrating the example of the method of connecting the transfer blade and the transfer arm of the semiconductor manufacturing apparatus according to the modification of the first embodiment (second view).

FIG. 13 is a schematic diagram illustrating a configuration of a semiconductor manufacturing apparatus according to a second embodiment.

FIG. 14 is a flowchart for illustrating a semiconductor manufacturing method according to the second embodiment.

FIG. 15A is a schematic diagram illustrating a configuration of a semiconductor manufacturing apparatus according to a third embodiment.

FIG. 15B is a schematic view illustrating a configuration of a processing chamber of the semiconductor manufacturing apparatus according to the third embodiment.

FIG. 16A is a schematic diagram illustrating a configuration of a semiconductor manufacturing apparatus according to a fourth embodiment.

FIG. 16B is a schematic view illustrating a configuration of a processing chamber of the semiconductor manufacturing apparatus according to the fourth embodiment.

FIG. 17 is a schematic diagram illustrating a configuration of a semiconductor manufacturing apparatus according to modification of the fourth embodiment.

### DETAILED DESCRIPTION

Embodiments provide a semiconductor manufacturing apparatus and a semiconductor manufacturing method capable of preventing positional displacement of a wafer in a transfer device during transfer of the wafer.

In general, according to at least one embodiment, there is provided a semiconductor manufacturing apparatus including a transfer device that includes a transfer blade whose mounting area on which a wafer is mounted is defined on a front surface and a transfer arm adjusting a position of the transfer blade, and a processing chamber that accommodates the transfer blade and is for removing foreign matter adhering to the mounting area.

Next, at least one embodiment will be described with reference to the drawings. In the description of the drawings described below, the same or similar portions are designated by the same or similar reference numerals. The drawings are schematic. The embodiments described below illustratively describe devices and methods for embodying the technical idea, and do not specify the material, shape, structure, disposition, etc. of the parts. Various changes may be made to the embodiments.

### First Embodiment

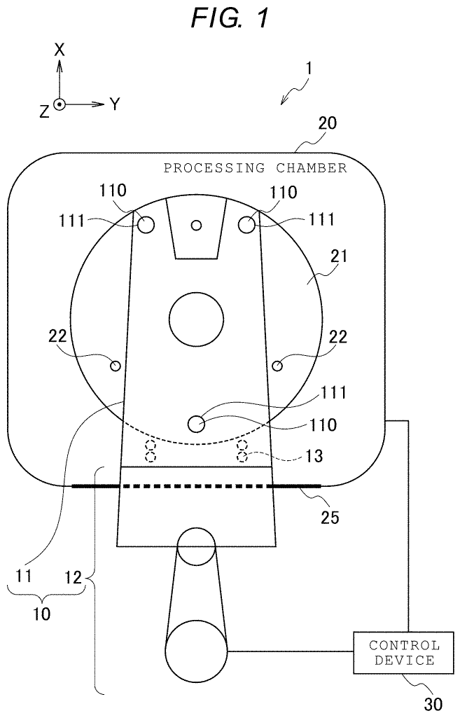

A semiconductor manufacturing apparatus 1 according to a first embodiment illustrated in FIG. 1 is used in a semiconductor manufacturing method for forming a semiconductor device on a wafer. The semiconductor manufacturing apparatus 1 includes a transfer device 10 including a transfer blade 11 whose mounting area 110 on which a wafer is mounted is defined on a front surface thereof and a processing chamber 20 for accommodating the transfer blade 11 and removing foreign matter adhering to the mounting area 110. As illustrated in FIG. 1, the processing chamber 20 is disposed outside the transfer device 10.

In FIG. 1, a plane normal line direction of the mounting area 110 is defined as the Z-axis direction, and a plane perpendicular to the Z-axis direction is defined as the XY-plane (the same applies hereinafter). The X-axis direction is the direction in which the transfer blade 11 is carried into the processing chamber 20. FIG. 1 is a plan view of the processing chamber 20 with the transfer blade 11 accommodated, when viewed from the Z-axis direction.

During transfer of the wafer by the transfer device 10, a phenomenon in which positional displacement of the wafer (hereinafter, also referred to as “transfer displacement”) occurs in the mounting area 110 was observed. The present inventors have repeatedly studied, and found that after a film is formed on a rear surface of the wafer in a manufacturing process of the semiconductor device, a part of the film peeled off from the rear surface of the wafer (hereinafter, referred to as “foreign matter”) adheres to the mounting area 110, which is the cause of the transfer displacement. That is, when the foreign matter is interposed between the mounting area 110 and the wafer, the wafer is not stable on the mounting area 110. The semiconductor manufacturing apparatus 1 removes foreign matter adhering to the mounting area 110 before the transfer displacement occurs.

The transfer device 10 includes a transfer arm 12 that is connected to the transfer blade 11 and adjusts a position of the transfer blade 11. The transfer arm 12 is, for example, a robot arm having a degree of freedom of a plurality of axes. The transfer blade 11 is fixed to the transfer arm 12 by a joining pin 13.

The semiconductor manufacturing apparatus 1 further includes a control device 30 that controls the operation of the transfer device 10 and the processing chamber 20. The control device 30 controls the transfer device 10 to accommodate the transfer blade 11 in the processing chamber 20, and controls a removal apparatus in the processing chamber 20 to remove the foreign matter adhering to the mounting area 110. Hereinafter, a process of moving the transfer blade 11 into the processing chamber 20 and removing the foreign matter adhering to the mounting area 110 is also referred to as a “foreign matter removal process”. In FIG. 1, the removal apparatus is not illustrated in order to clarify a basic configuration of the transfer device 10 and the processing chamber 20. Details of the removal apparatus of the processing chamber 20 will be described later.

Before describing the details of the foreign matter removal process, the transfer blade 11 and the processing chamber 20 will be described with reference to FIG. 1.

In the transfer device 10 illustrated in FIG. 1, an upper surface of a pad 111 disposed on a front surface of the transfer blade 11 is the mounting area 110 on which the wafer is mounted. FIG. 1 illustrates a state in which the wafer is not mounted on the transfer blade 11.

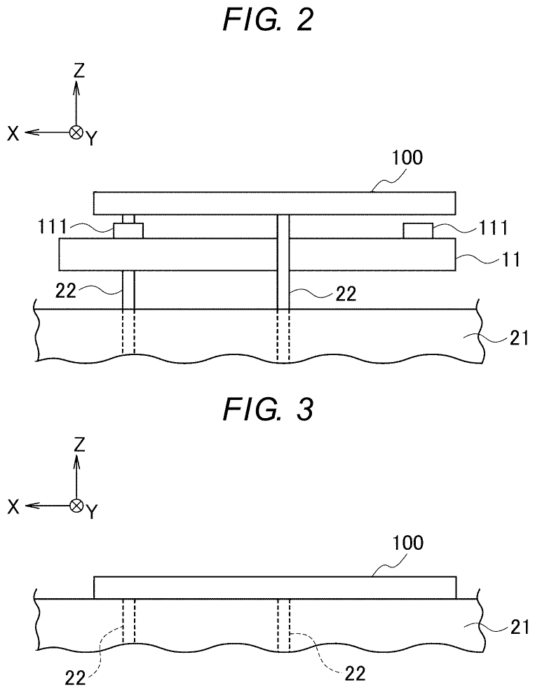

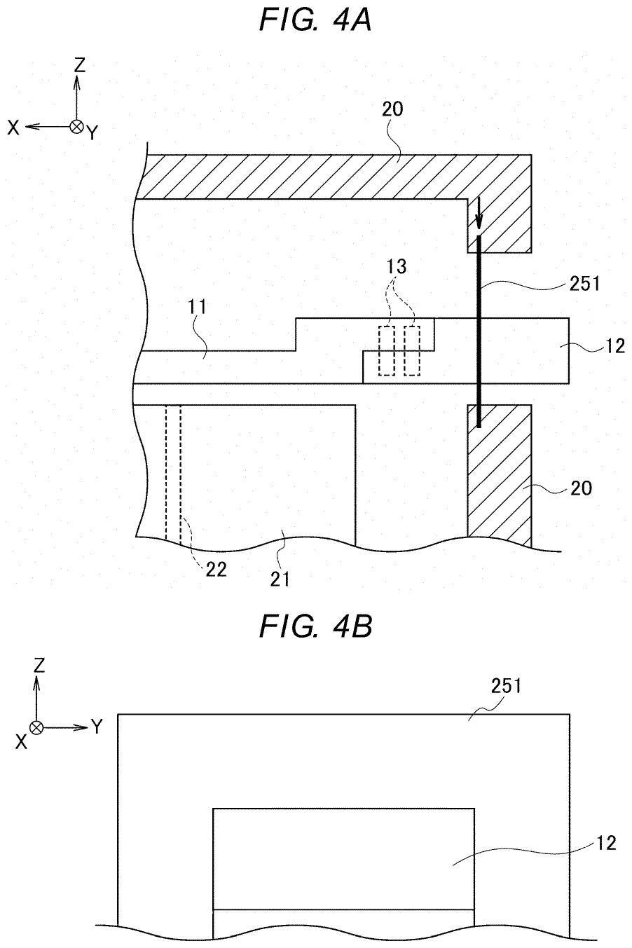

A stage 21 illustrated in FIG. 1 is an area on which the wafer accommodated in the processing chamber 20 is placed. A pusher pin for wafer 22 is used when the wafer is carried into the processing chamber 20 and the wafer is carried out from the processing chamber 20 by the transfer device 10. For example, when the transfer device 10 carries a wafer 100 into the processing chamber 20, as illustrated in FIG. 2, the pusher pin for wafer 22 whose upper surface is exposed to an upper surface of the stage 21 supports the wafer 100. In this state, the transfer blade 11 is pulled out from below the wafer 100. After that, the entire pusher pin for wafer 22 is stored in the stage 21, and the wafer 100 is placed on the stage 21 as illustrated in FIG. 3. On the other hand, when the wafer 100 is carried out from the processing chamber 20, an upper portion of the pusher pin for wafer 22 is exposed to the upper surface of the stage 21 and the wafer 100 is lifted up. In this state, the transfer blade 11 is inserted below the wafer 100. Then, by storing the entire pusher pin for wafer 22 in the stage 21, the wafer 100 is mounted on the transfer blade 11. After that, the transfer device 10 carries out the wafer 100 from the processing chamber 20.

The processing chamber 20 includes a shutter 25 that opens and closes a transfer port for carrying the transfer blade 11 into the processing chamber 20. Normally, the manufacturing process in the processing chamber 20 is performed inside the processing chamber 20 in which the shutter 25 is closed to form a sealed space. That is, in the foreign matter removal process, the foreign matter adhering to the mounting area 110 of the transfer blade 11 accommodated in the processing chamber 20 is removed with the shutter 25 closed.

In the semiconductor manufacturing apparatus 1, the transfer port may be closed by the shutter 25 with the transfer arm 12 interposed between the shutter 25. An example of closing the shutter 25 with the transfer arm 12 interposed between the shutter 25 will be described below. The shutter 25 described below is configured with a first shutter 251 to a fourth shutter 254 disposed along the X-axis direction.

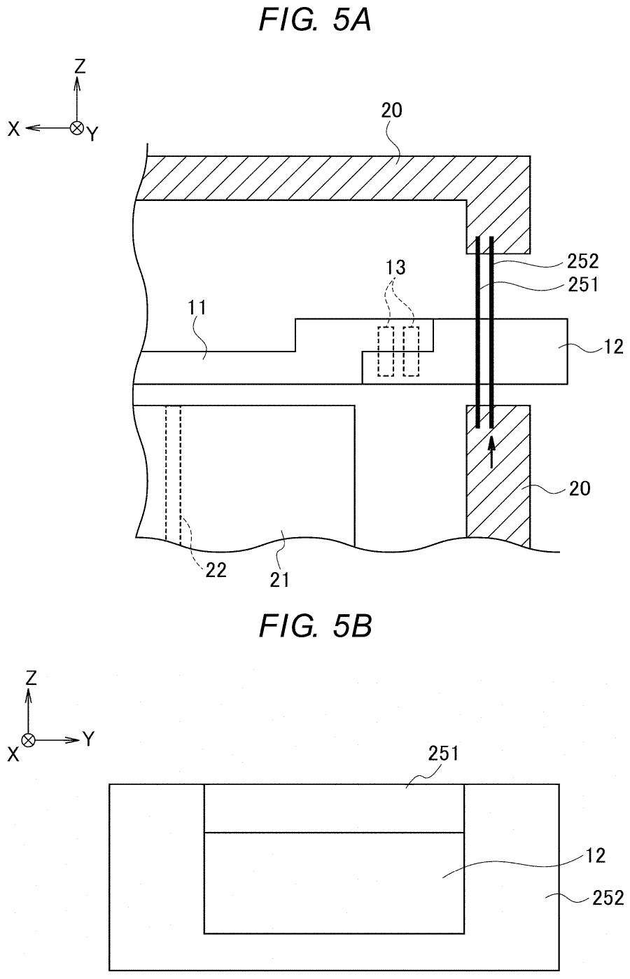

As illustrated in FIG. 4A, the first shutter 251 descends from above the transfer port of the processing chamber 20. As illustrated in FIG. 4B, the first shutter 251 has a U-shape in which an opening area having a width corresponding to the width of the transfer arm 12 opens downward. For that reason, by closing the first shutter 251 until the first shutter 251 comes into contact with the transfer arm 12, the transfer port of the processing chamber 20 is opened only below the transfer arm 12.

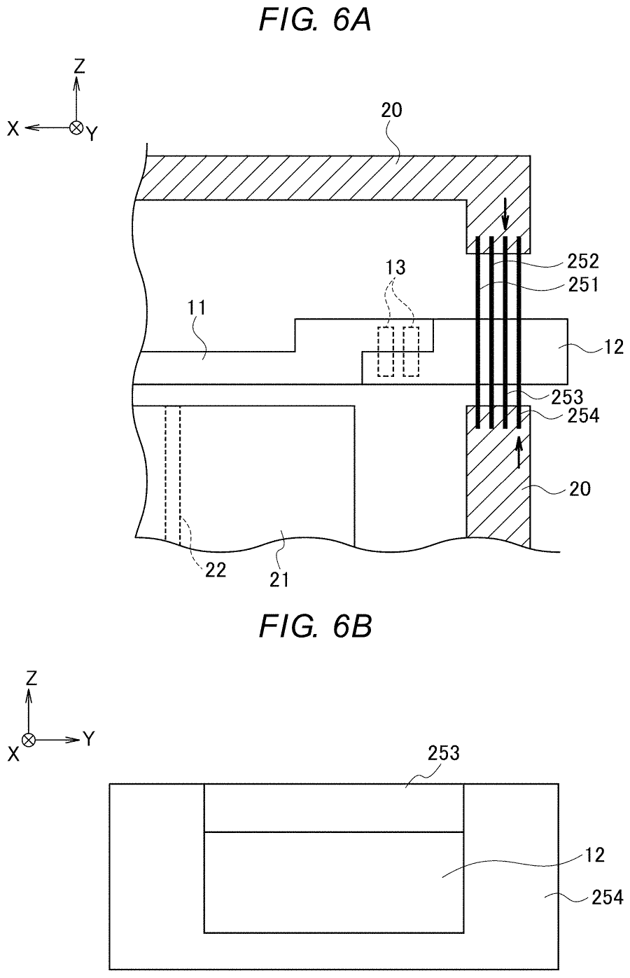

Next, as illustrated in FIG. 5A, the second shutter 252 ascends from below the transfer port of the processing chamber 20. As illustrated in FIG. 5B, the second shutter 252 has a U-shape in which an opening area having a width corresponding to the width of the transfer arm 12 opens upward. For that reason, by closing the second shutter 252 until the second shutter 252 comes into contact with the transfer arm 12, the transfer port of the processing chamber 20 is closed with the transfer arm 12 interposed between the first shutter 251 and the second shutter 252.

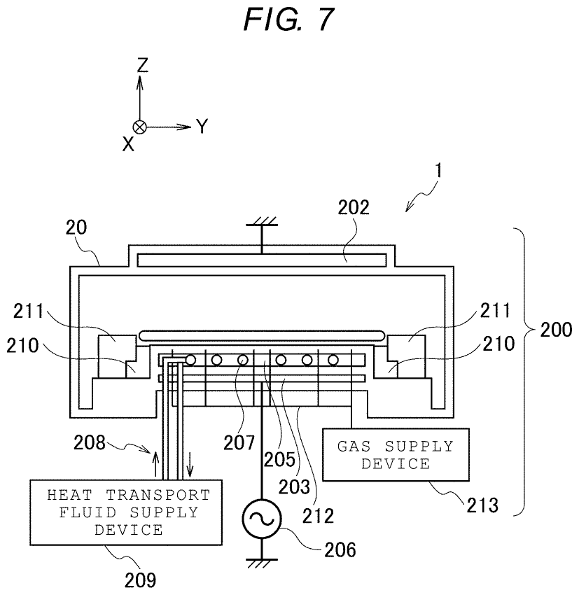

Furthermore, as illustrated in FIGS. 6A and 6B, the third shutter 253 descends from above the transfer port, and the fourth shutter 254 ascends from below the transfer port of the processing chamber 20. With this configuration, the transfer arm 12 is interposed between the third shutter 253 and the fourth shutter 254. Similar to the first shutter 251, the third shutter 253 has a U-shape in which an opening area having a width corresponding to the width of the transfer arm 12 opens downward. Similar to the second shutter 252, the fourth shutter 254 has a U-shape in which an opening area having a width corresponding to the width of the transfer arm 12 opens upward.

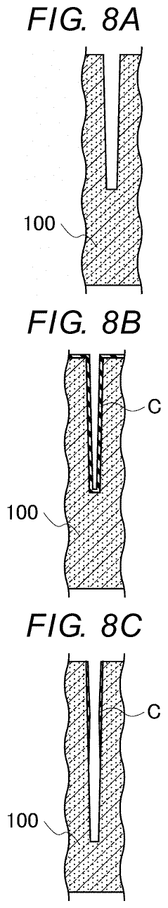

FIG. 7 illustrates an example of a configuration of the processing chamber 20 including a removal apparatus 200. In the foreign matter removal process using the removal apparatus 200 illustrated in FIG. 7, foreign matter is removed from the mounting area 110 by generating plasma inside the processing chamber 20 and exposing the mounting area 110 to the plasma (hereinafter, also referred to as “plasma processing”). In the foreign matter removal process by plasma processing, gas being turned into plasma is made to react with the foreign matter adhering to the mounting area 110 to remove the foreign matter from the mounting area 110. The removal apparatus 200 illustrated in FIG. 7 includes an upper electrode 202, a lower electrode 203, and a high frequency power supply 206. The transfer blade 11 which is a target of the foreign matter removal process is placed on an insulator placement table 205. A lower dummy ring 210 and an upper dummy ring 211 are disposed in a ring shape around the insulator placement table 205.

With the transfer blade 11 placed on the insulator placement table 205, gas to be turned into plasma is adjusted to a predetermined pressure inside the processing chamber 20, and then the high frequency power supply 206 supplies power between the upper electrode 202 and the lower electrode 203. With this configuration, the gas inside the processing chamber 20 is turned into plasma. By exposing the transfer blade 11 to plasma, the foreign matter adhering to the mounting area 110 is removed. For example, when a main component of the foreign matter adhering to the transfer blade 11 is carbon, plasma processing may be performed by turning gas containing oxygen as the main component into plasma. That is, carbon is volatilized by plasma processing in which oxygen and carbon are made to react with each other to generate carbon dioxide, and the foreign matter is removed from the transfer blade 11.

In the removal apparatus 200 illustrated in FIG. 7, a heat transport fluid flow path 207 disposed on the insulator placement table 205 controls a temperature of the transfer blade 11 placed on the insulator placement table 205. Fluid for heat exchange is supplied from a heat transport fluid supply device 209 to the heat transport fluid flow path 207 via a heat transport fluid pipe 208. A heat exchange gas flow path 212 connected to a heat exchange gas supply device 213 is disposed inside the processing chamber 20.

In the above, an example in which the foreign matter adhering to the mounting area 110 is carbon has been described. However, it goes without saying that the foreign matter adhering to the mounting area 110 may be other than carbon. A type and flow rate of gas to be turned into plasma inside the processing chamber 20 are appropriately set according to the foreign matter adhering to the mounting area 110. For the gas to be turned into plasma, a gas that does not affect the material and shape of the transfer blade 11, such as removing foreign matter from the mounting area 110 and not scraping the front surface of the transfer blade 11, is selected.

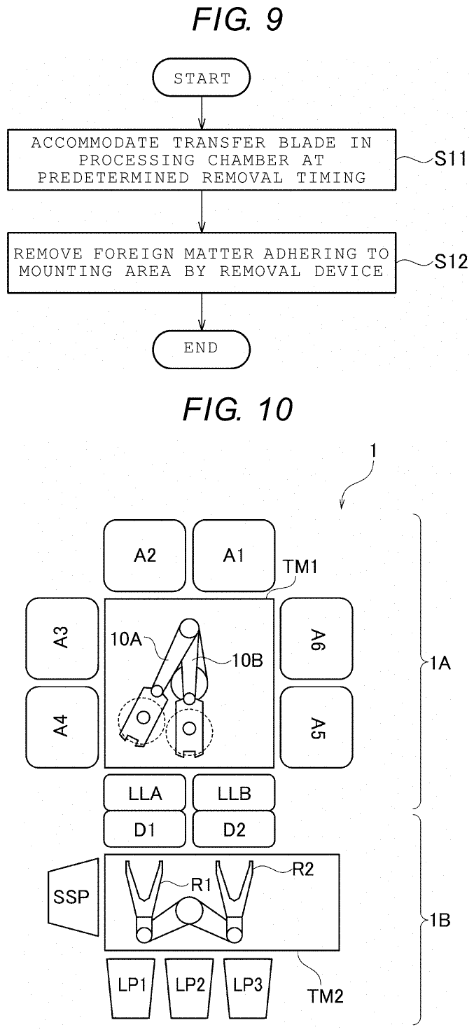

By the way, a process of generating foreign matter adhering to the mounting area 110 (hereinafter, also referred to as “foreign matter generation process”) is, for example, a process of forming a protective film. This protective film is formed to protect an area which is not to be etched in a dry etching process such as reactive ion etching (RIE). An example of the foreign matter generation process will be described below with reference to FIGS. 8A to 8C. The manufacturing process illustratively described below is a process of forming a groove having a high aspect ratio on the wafer.

As illustrated in FIG. 8A, a groove is formed on the front surface of the wafer 100. After that, as illustrated in FIG. 8B, a carbon film C is formed as a protective film on inner wall surfaces of the groove. In this case, the carbon film is also formed on the rear surface of the wafer 100. After that, as illustrated in FIG. 8C, the groove is further deepened by the dry etching method using the carbon film C as the protective film. In this case, the carbon film C formed on the inner wall surfaces of the groove is scraped to some extent. After that, the carbon film C remaining on the inner wall surfaces of the groove is removed.

After the groove is deeply formed by the dry etching method described above, the wafer 100 is forwarded to a next manufacturing process. In this case, since the wafer 100 is transferred by the transfer device 10, the rear surface of the wafer 100 and the mounting area 110 of the transfer blade 11 come into contact with each other. For that reason, the carbon film remaining on the rear surface of the wafer 100 is peeled off, and the peeled carbon film adheres to the mounting area 110 of the transfer blade 11 as foreign matter.

As the number of foreign matter generation processes is increased, the number of foreign matter adhering to the mounting area 110 increases. The semiconductor manufacturing apparatus 1 removes the foreign matter from the mounting area 110 before the transfer displacement occurs due to the foreign matter adhering to the mounting area 110. With this configuration, the transfer displacement of the wafer can be prevented.

The timing for executing the foreign matter removal process (hereinafter, also referred to as “removal timing”) can be freely set.

For example, the removal timing may be set according to the number of times the wafer is mounted on the transfer blade (hereinafter, referred to as “the number of times of mounting”) immediately after the foreign matter generation process in which the film is formed on the rear surface of the wafer. In this case, the number of times of mounting that causes the transfer displacement in the transfer device 10 is obtained in advance by an experiment or the like. For example, the control device 30 records the number of times of mounting, and when the number of times of mounting reaches a fixed number of times, the control device 30 automatically executes the foreign matter removal process.

Alternatively, the foreign matter removal process may be executed every time a fixed period of time elapses, regardless of the number of times of mounting. That is, the control device 30 automatically executes the foreign matter removal process after a predetermined period set in advance has elapsed from the previous foreign matter removal process. In order to set an interval between the foreign matter removal processes, for example, the period during which the transfer displacement is caused in the transfer device 10 is obtained in advance by an experiment or the like.

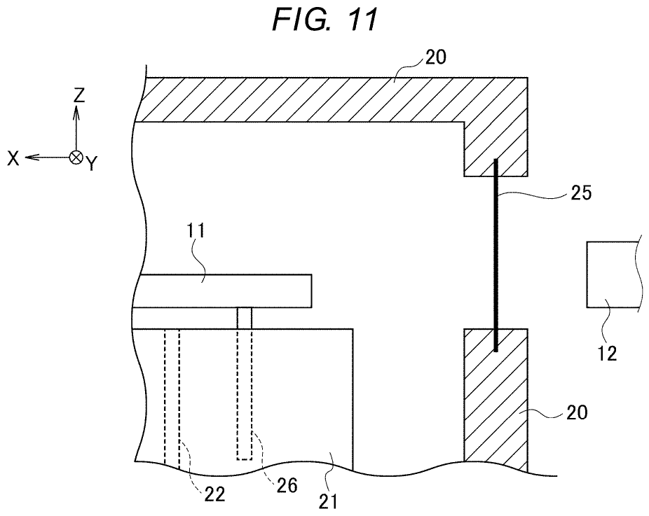

FIG. 9 illustrates an example of the foreign matter removal process by the semiconductor manufacturing apparatus 1 according to the first embodiment. First, in step S11 of FIG. 9, at a predetermined removal timing, the transfer blade 11 whose mounting area 110 on which the wafer is mounted is defined on a front surface is accommodated in the processing chamber 20. Then, in step S12, a foreign matter removing process of removing the foreign matter adhering to the mounting area 110 is executed in the processing chamber 20.

The foreign matter removal process described above may be executed under the control of the control device 30. In that case, the control device 30 controls the transfer device 10 so that the transfer blade 11 is accommodated in the processing chamber 20 at a specific removal timing which is set. Then, the control device 30 controls the removal apparatus 200 so as to remove the foreign matter adhering to the mounting area 110 of the transfer blade 11 accommodated in the processing chamber 20.

Alternatively, an operator who operates the semiconductor manufacturing apparatus 1 may execute the foreign matter removal process. For example, in the semiconductor manufacturing apparatus 1 that does not include the control device 30, the operator who operates the semiconductor manufacturing apparatus 1 may operate the transfer device 10 and the processing chamber 20 at a predetermined removal timing to execute the foreign matter removal process.

The processing chamber 20 may be a dedicated chamber for executing the foreign matter removal process, or may also serve as a chamber for executing another manufacturing process. For example, the foreign matter removal process may be executed in a chamber where an ashing process by plasma processing is performed in the manufacture of a semiconductor device. Normally, in the dry etching process in the manufacture of the semiconductor device, a carbon film is often used as a mask material during processing. After the dry etching process, the ashing process is executed in the subsequent steps to remove an unnecessary masking material. In this ashing process, carbon is removed from the wafer by, for example, plasma processing in which gas containing oxygen as a main component is turned into plasma with the wafer heated. For that reason, the chamber for executing the ashing process may also serve as the processing chamber 20.

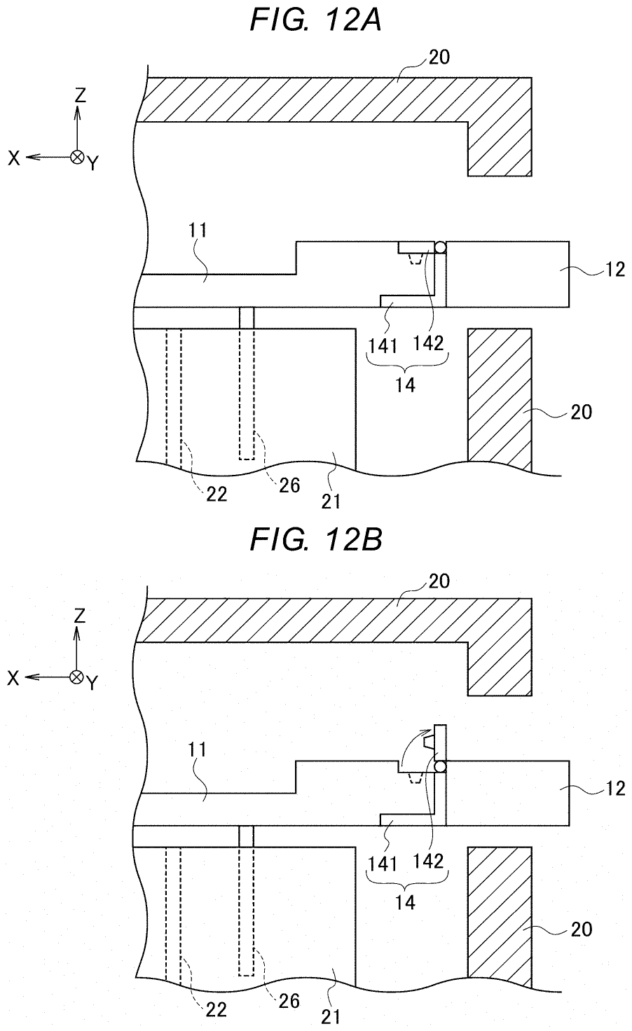

The semiconductor manufacturing apparatus 1 may include a plurality of chambers. FIG. 10 illustrates an example of the semiconductor manufacturing apparatus 1 including the plurality of chambers. The semiconductor manufacturing apparatus 1 illustrated in FIG. 10 includes a first processing device LA including chambers A1 to A6 and a second processing device 1B coupled to the first processing device LA. In the semiconductor manufacturing apparatus 1 illustrated in FIG. 10, the foreign matter removal process is executed in any of the chambers A1 to A6.

The first processing device 1A carries out the dry etching process such as RIE. The first processing device 1A includes a first storage chamber LLA and a second storage chamber LLB for storing wafers to be transferred to and from the second processing device 1B. Inside the first processing device 1A, the wafer is transferred by a first transfer device 10A and a second transfer device 10B of a first transfer module TM1.

The second processing device 1B includes a first load port LP1 to a third load port LP3 for coupling the wafer to a container for transferring the wafer in a clean room, and a first ashing chamber D1 and a second ashing chamber D2 for performing the ashing process. A silicon storage port SSP of the second processing device 1B accommodates a dummy substrate used for cleaning processing of the asking chamber. Inside the second processing device 1B, the wafer is transferred by a first robot arm R1 and a second robot arm R2 of a second transfer module TM2.

The first storage chamber LLA and the second storage chamber LLB are carry-in and out ports for transferring the wafer between the inside of the second processing device 1B which is kept at atmospheric pressure and the inside of the first processing device 1A which is kept in vacuum. In the first processing device 1A, a plurality of processes can be continuously executed in vacuum without exposing the inside of each chamber to the atmosphere. For that reason, the manufacturing process can be made more efficient.

The first transfer module TM1 and the second transfer module TM2 each have two transfer arms. For that reason, two wafers can be simultaneously transferred inside the first processing device 1A and the second processing device 1B to improve productivity.

When the semiconductor manufacturing apparatus 1 includes a plurality of chambers, wafer processing for forming the semiconductor device on the wafer and the foreign matter removal process may be performed in parallel. That is, one of the chambers of the semiconductor manufacturing apparatus 1 may be used as the processing chamber 20 to execute the foreign matter removal process, and the wafer processing may be executed in another chamber in parallel with the foreign matter removal process. Even when the chamber for executing the wafer processing also serves as the processing chamber 20, the foreign matter removal process may be executed in the processing chamber 20 in parallel with the wafer processing while executing the wafer processing in the chamber that does not also serve as the processing chamber 20.

When the transfer displacement occurs in the semiconductor manufacturing apparatus, the wafer may be damaged due to the wafer falling from the transfer device or the wafer colliding with the manufacturing apparatus for which the wafer is to be carried in. In order to redispose the wafer in the mounting area, the manufacturing process needs to be stopped. As such, when the transfer displacement occurs, the productivity in manufacturing the semiconductor device decreases.

However, the semiconductor manufacturing apparatus 1 according to the first embodiment removes the foreign matter adhering to the mounting area 110 at a predetermined removal timing. For that reason, according to the semiconductor manufacturing apparatus 1, the occurrence of transfer displacement during transfer of the wafer by the transfer device 10 can be prevented. As a result, a decrease in the productivity of manufacturing the semiconductor device can be prevented.

### Modification

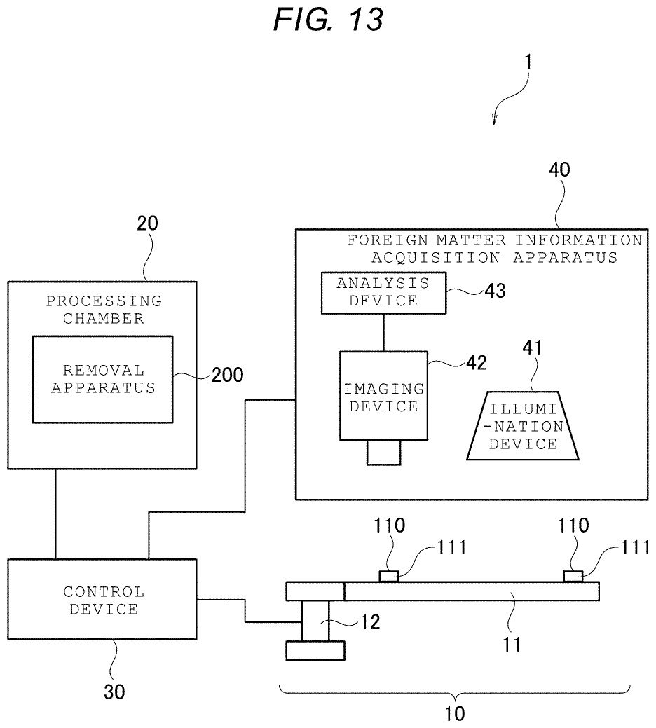

In the above, a case where the transfer port of the processing chamber 20 is closed by the shutter 25 with the transfer arm 12 interposed between the shutter 25 has been described. In contrast, only the transfer blade 11 may be accommodated in the processing chamber 20 by using the transfer device 10 in which the transfer blade 11 is connected so as be attachable to and detachable from the transfer arm 12. That is, as illustrated in FIG. 11, the shutter 25 is closed with the transfer blade 11 separated from the transfer arm 12 is accommodated in the processing chamber 20 and the transfer arm 12 is positioned outside the processing chamber 20. Since the transfer arm 12 is not interposed in the shutter 25, the inside of the processing chamber 20 can be more reliably sealed.

As illustrated in FIG. 11, the transfer blade 11 may be brought into a state of being separated from the stage 21 by using a pusher pin for transfer blade 26. The pusher pin for transfer blade 26 is used when the transfer blade 11 is carried into the processing chamber 20 or the transfer blade 11 is carried out from the processing chamber 20. That is, when the transfer blade is carried into the processing chamber 20, the upper portion of the pusher pin for transfer blade 26 is exposed to the upper surface of the stage 21, and the transfer blade 11 is supported above the stage 21. In this state, the transfer blade 11 and the transfer arm 12 are separated. When the wafer in the processing chamber 20 is accommodated, the entire pusher pin for transfer blade 26 is stored inside the stage 21.

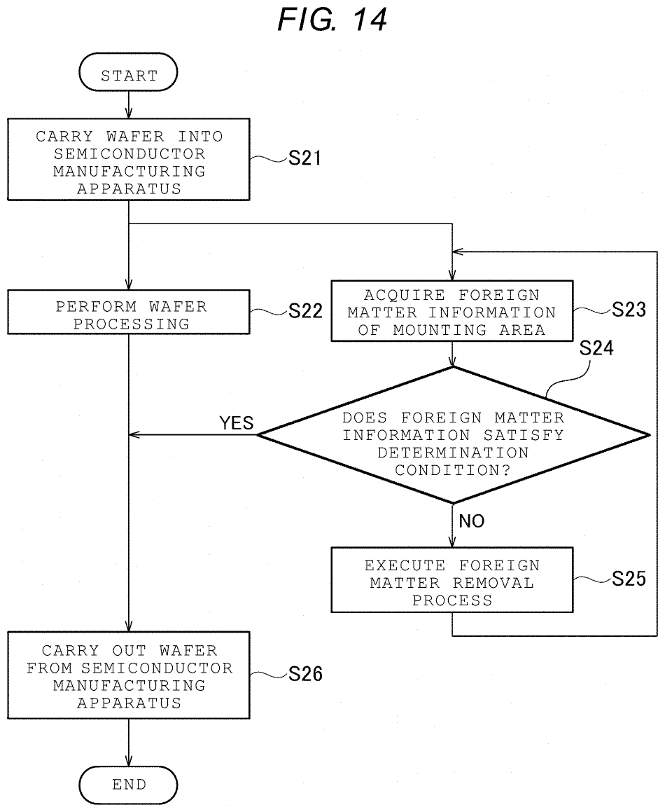

Various methods are possible for the transfer blade 11 to be connected so as to be attachable to and detachable from the transfer arm 12. For example, as illustrated in FIGS. 12A to 12B, the transfer blade 11 may be connected so as to be attachable to and detachable from the transfer arm 12 by using a clamp part 14. A first portion 141 of the clamp part 14 is fixed to the transfer arm 12. A second portion 142 of the clamp part 14 is connected to the first portion 141 so as to be rotatably movable with respect to the first portion 141 with the Y-axis direction as the rotation axis.

As illustrated in FIG. 12A, the transfer blade 11 and the transfer arm 12 are connected by engaging a protrusion formed on the second portion 142 with a recess portion formed on the transfer blade 11. Then, as illustrated by the arrow in FIG. 12B, as the second portion 142 of the clamp part 14 rotates, the protrusion formed on the second portion 142 is disengaged from the recess portion formed on the transfer blade 11. With this configuration, the transfer blade 11 and the transfer arm 12 are separated.

In the above, an example in which the transfer blade 11 is connected so as to be attachable to and detachable from the transfer arm 12 by engaging the protrusion formed on the clamp part 14 with the recess portion formed on the transfer blade 11 or disengaging the protrusion from the recess portion has been described. The transfer blade 11 may be connected so as to be attachable to and detachable from the transfer arm 12 by another method. For example, an electromagnet may be disposed on the transfer blade 11 and the transfer arm 12, and the transfer blade 11 and the transfer arm 12 may be connected by magnetic force. Alternatively, the transfer blade 11 and the transfer arm 12 may be connected by vacuum suction.

### Second Embodiment

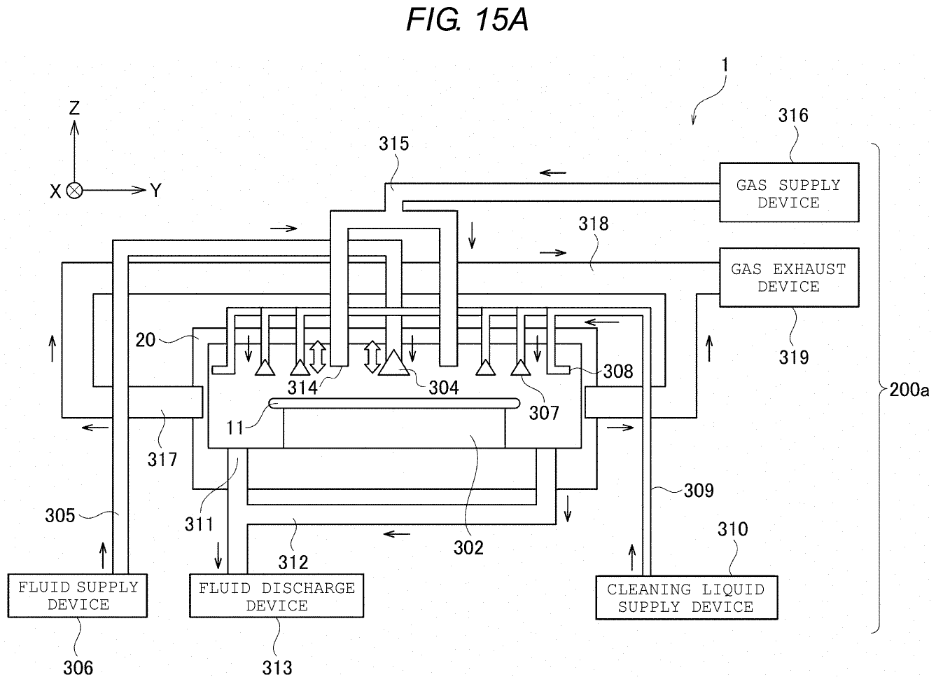

As illustrated in FIG. 13, the semiconductor manufacturing apparatus 1 according to a second embodiment further includes a foreign matter information acquisition apparatus 40. The foreign matter information acquisition apparatus 40 acquires information indicating an adhering state of foreign matter in the mounting area 110 (hereinafter, also referred to as “foreign matter information”). The foreign matter information is, for example, information such as the number and range of foreign matter adhering to the mounting area 110. The semiconductor manufacturing apparatus 1 illustrated in FIG. 13 determines the removal timing based on the foreign matter information. The semiconductor manufacturing apparatus 1 illustrated in FIG. 13 is different from that of FIG. 1 in that the semiconductor manufacturing apparatus 1 includes the foreign matter information acquisition apparatus 40. The rest of configurations of the semiconductor manufacturing apparatus 1 illustrated in FIG. 13 are the same as those of the semiconductor manufacturing apparatus 1 illustrated in FIG. 1.

The foreign matter information acquisition apparatus 40 includes an illumination device 41 that irradiates the mounting area 110 of the transfer blade 11 with illumination light, an imaging device 42 that acquires an image of the front surface of the mounting area 110, and an analysis device 43 that analyzes the image acquired by the imaging device 42. The analysis device 43 acquires foreign matter information by analyzing the front surface of the mounting area 110 using, for example, an optical diffraction method.

The acquisition of foreign matter information by the foreign matter information acquisition apparatus 40 may be executed in parallel with wafer processing, for example, while the wafer processing is being executed as part of the manufacturing process of the semiconductor device. Alternatively, the foreign matter information acquisition apparatus 40 may acquire foreign matter information at the timing when the wafer processing is not performed.

In the semiconductor manufacturing apparatus 1 illustrated in FIG. 13, the control device 30 executes the foreign matter removal process when the foreign matter information obtained by the foreign matter information acquisition apparatus 40 does not satisfy a predetermined determination condition.

The determination condition may be set as, for example, foreign matter information for a state where the transfer device 10 is at a limit where a transfer displacement does not occur in the transfer device 10. That is, the foreign matter information of the mounting area 110 in a state where the transfer displacement does not occur is acquired in advance by an experiment or the like, and the foreign matter information at this time is set as the determination condition. Then, the determination condition is compared with the foreign matter information acquired by the foreign matter information acquisition apparatus 40, and the foreign matter removal process is executed before the transfer displacement occurs. For example, when the number of foreign matter obtained as foreign matter information is larger than the number of foreign matter in the determination condition, the control device 30 executes the foreign matter removal process.

The foreign matter information acquisition apparatus 40 may be disposed in the same area as the transfer device 10 inside the semiconductor manufacturing device 1. Alternatively, the foreign matter information acquisition apparatus 40 may be disposed in any of the plurality of chambers illustrated in FIG. 10. For example, the foreign matter information acquisition apparatus 40 is disposed in a chamber A5 of FIG. 10, and a chamber A6 is used as the processing chamber 20. That is, the transfer blade 11 is transferred to the chamber A5, and the foreign matter information acquisition apparatus 40 acquires foreign matter information about the transfer blade 11. The control device 30 determines, based on the foreign matter information, whether or not the foreign matter removing process of the transfer blade 11 is needed.

When the control device 30 determines that the foreign matter removal process is needed, the control device 30 controls the transfer device 10 to transfer the transfer blade 11 to the processing chamber 20. Then, the control device 30 causes the foreign matter removal process to be executed in the processing chamber 20. On the other hand, when the control device 30, based on the foreign matter information, determines that the foreign matter removal process is not needed, the foreign matter removal process is not executed.

In the above, a case where the control device 30, based on the foreign matter information, determines whether or not the foreign matter removal process is needed has been described. However, the operator who operates the semiconductor manufacturing apparatus 1 may determine whether or not the foreign matter removal process is needed. For example, the operator may observe the image of the front surface of the mounting area 110 acquired by the imaging device 42 of the foreign matter information acquisition apparatus 40, and visually determine whether or not the foreign matter removal process is needed.

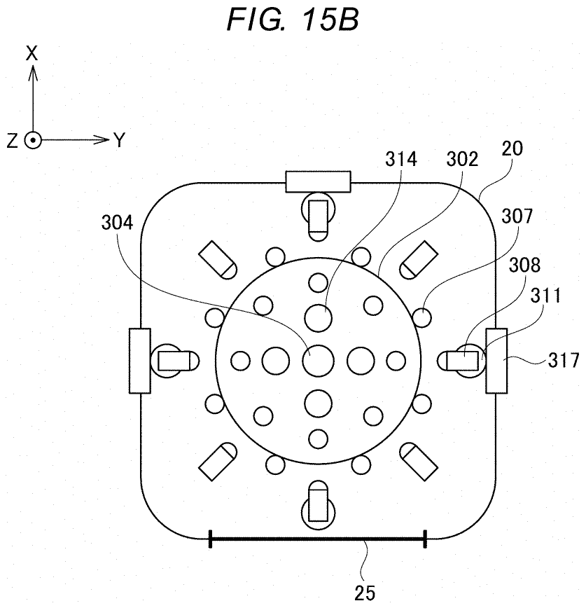

Hereinafter, an example of a manufacturing method using foreign matter information will be described with reference to FIG. 14. In the following, a case where the foreign matter information is acquired while the semiconductor manufacturing apparatus 1 is executing wafer processing will be illustratively described. However, the semiconductor manufacturing apparatus 1 that executes the foreign matter removal process and the semiconductor manufacturing apparatus that performs the wafer processing may be different.

First, in step S21 of FIG. 14, a wafer which is a processing target is carried into the semiconductor manufacturing apparatus 1. For example, the wafer is carried into a chamber for processing the wafer by the transfer device 10. Then, in step S22, the wafer processing in the semiconductor manufacturing apparatus 1 is performed.

While executing the wafer processing in step S22, in step S23, the foreign matter information acquisition apparatus 40 acquires the foreign matter information of the mounting area 110 of the transfer blade 11. Then, in step S24, the control device 30 determines whether or not the foreign matter information of the mounting area 110 satisfies a predetermined determination condition.

When it is determined that the foreign matter information satisfies the determination condition in step S24, the process of the semiconductor manufacturing method proceeds to step S26. In step S26, after the wafer processing is performed, the wafer is carried out from the semiconductor manufacturing apparatus 1 by the transfer device 10.

On the other hand, when it is determined that the foreign matter information does not satisfy the determination condition in step S24, the process of the semiconductor manufacturing method proceeds to step S25. In step S25, the transfer blade 11 is accommodated in the processing chamber 20 and the foreign matter removal process is executed. After the foreign matter removal process, the process of the semiconductor manufacturing method returns to step S23. Then, steps S23 to S25 are repeated until the foreign matter information satisfies the determination condition.

In the semiconductor manufacturing apparatus 1 according to the second embodiment, the removal timing is set based on the foreign matter information. According to the semiconductor manufacturing apparatus 1 including the foreign matter information acquisition apparatus 40, the foreign matter can be removed from the mounting area 110 before the transfer displacement occurs, based on the state of the foreign matter adhering to the mounting area 110. Others are substantially the same as those in the first embodiment, and duplicate description thereof is omitted.

### Third Embodiment

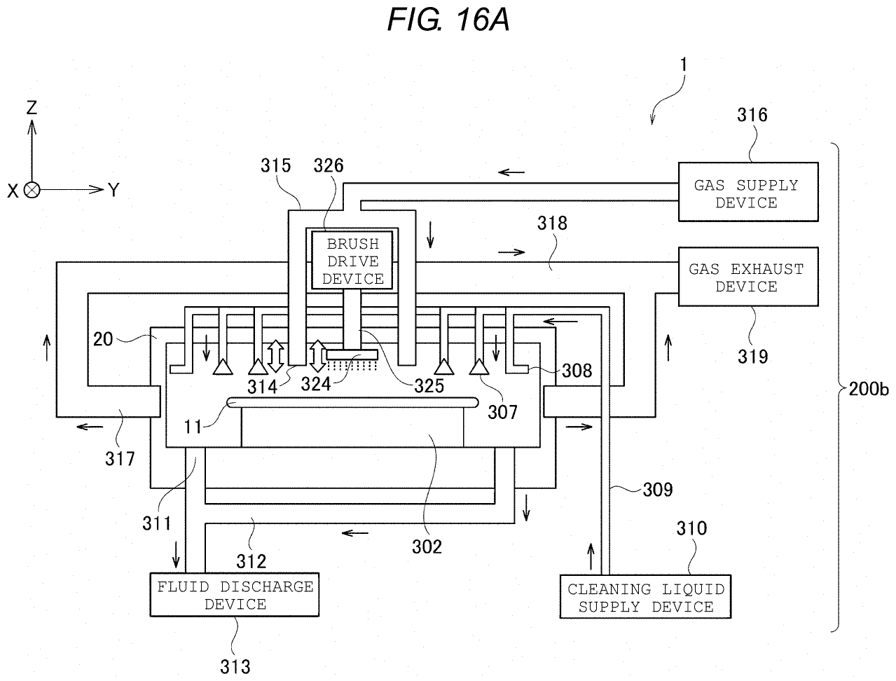

The method of removing the foreign matter from the mounting area 110 by plasma processing has been described above. Alternatively, the foreign matter may be removed from the mounting area 110 by a method other than plasma processing. FIG. 15A illustrates a configuration of the semiconductor manufacturing apparatus 1 according to a third embodiment. FIG. 15A is a side view of the semiconductor manufacturing apparatus 1 when viewed from the transfer port side of the processing chamber 20. FIG. 15B is a plan view of the processing chamber 20 when viewed from the Z-axis direction. The semiconductor manufacturing apparatus 1 illustrated in FIG. 15A includes a removal apparatus 200a removing foreign matter adhering to the mounting area 110 with liquid or gas. The arrow illustrated in FIG. 15A indicates the direction of a flow of liquid or gas.

In the foreign matter removal process by the removal apparatus 200a, liquid for processing for washing off the foreign matter from the mounting area 110 (hereinafter, also referred to as “processing liquid”) is jetted from a fluid outflow port 304 to the transfer blade 11 placed on an insulator placement table 302. The processing liquid is supplied from a fluid supply device 306 to the fluid outflow port 304 via a fluid supply flow path 305.

In the foreign matter removal process by the removal apparatus 200a, gas for processing for blowing off the foreign matter from the mounting area 110 (hereinafter, also referred to as “processing gas”) is blown out to the transfer blade 11 from a gas jet port 314. The processing gas is supplied from a gas supply device 316 to the gas jet port 314 via a gas supply path 315. The processing gas inside the processing chamber 20 is exhausted from a gas exhaust port 317 to a gas exhaust device 319 via a gas exhaust path 318.

The inside of the processing chamber 20 illustrated in FIGS. 15A and 15B is cleaned with cleaning liquid. The cleaning liquid is supplied from a cleaning liquid supply device 310 to a lower surface cleaning liquid outflow port 307 and a side surface cleaning liquid outflow port 308 via a cleaning liquid supply flow path 309. The cleaning liquid is jetted from the lower surface cleaning liquid outflow port 307 in the Z-axis direction, and the cleaning liquid is jetted from the side cleaning liquid outflow port 308 along the XY-plane. The processing liquid and the cleaning liquid inside the processing chamber 20 are discharged from a fluid discharge port 311 to a fluid discharge device 313 via a fluid discharge flow path 312.

As illustrated by the double-headed arrow in FIG. 15A, the fluid outflow port 304 and the gas jet port 314 may be movable along the Z-axis direction. With this configuration, the pressure and flow rate of the processing liquid and the processing gas applied to the transfer blade 11 can be adjusted by making a distance between the fluid outflow port 304 or the gas jet port 314 and the transfer blade 11 variable.

As described above, the removal apparatus 200a illustrated in FIG. 15A removes the foreign matter adhering to the mounting area 110 by the processing liquid and the processing gas. The foreign matter may be removed from the mounting area 110 by either the processing liquid or the processing gas. That is, the foreign matter removal process may include either or both of a process of cleaning the surface of the mounting area 110 by liquid and a process of blowing out gas to the surface of the mounting area 110.

In the semiconductor manufacturing apparatus 1 illustrated in FIG. 15A, the connection between the transfer blade 11 and the transfer arm 12 may be fixed or attachable to or detachable from each other. The removal timing may be set based on the foreign matter information.

### Fourth Embodiment

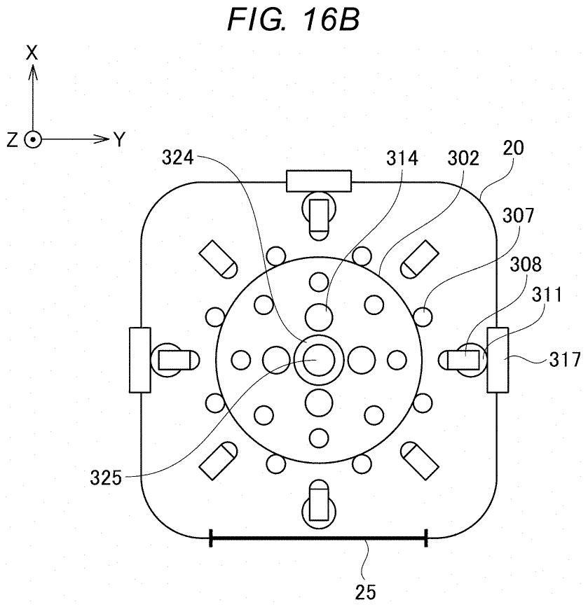

FIG. 16A illustrates a configuration of the semiconductor manufacturing apparatus 1 according to a fourth embodiment. FIG. 16A is a side view of the semiconductor manufacturing apparatus 1 when viewed from the transfer port side of the processing chamber 20. FIG. 16B is a plan view of the processing chamber 20 when viewed from the Z-axis direction. The semiconductor manufacturing apparatus 1 illustrated in FIG. 16A includes a removal apparatus 200b removing foreign matter adhering to the mounting area 110 by physically rubbing the front surface of the mounting area 110.

The removal apparatus 200b includes a brush 324 that comes into contact with the front surface of the mounting area 110, a brush drive unit 325 that drives the brush 324, and a brush drive device 326 that controls the brush drive unit 325. The semiconductor manufacturing apparatus 1 illustrated in FIG. 16A is different from the semiconductor manufacturing apparatus 1 illustrated in FIG. 15A in that the semiconductor manufacturing apparatus 1 illustrated in FIG. 16A includes the brush 324, the brush drive unit 325, and the brush drive device 326 instead of the fluid outflow port 304, the fluid supply flow path 305, the fluid supply device 306 of the removal apparatus 200a. The rest of the rest of configurations of the semiconductor manufacturing apparatus 1 illustrated in FIG. 16A are the same as those of the semiconductor manufacturing apparatus 1 illustrated in FIG. 15A.

In the semiconductor manufacturing apparatus 1 including the removal apparatus 200b, the brush drive unit 325 drives the brush 324 so that the brush 324 rubs the front surface of the mounting area 110 under the control of the brush drive device 326. For example, the brush 324 that is in contact with the front surface of the mounting area 110 moves in parallel with the XY-plane to remove the foreign matter adhering to the mounting area 110. As illustrated by the double-headed arrow in FIG. 16A, the brush drive unit 325 adjusts the position of the brush 324 along the Z-axis direction so that the brush 324 comes into contact with or separates from the front surface of the mounting area 110. FIG. 16A illustrates a state in which the front surfaces of the brush 324 and the mounting area 110 are separated from each other. The removal apparatus 200b can adjust strength with which the brush 324 rubs the front surface of the mounting area 110 by adjusting the position of the brush 324 along the Z-axis direction.

As described above, the foreign matter removal process may include a process of rubbing the front surface of the mounting area 110 with the brush 324 and scraping off the foreign matter from the mounting area 110. In the semiconductor manufacturing apparatus 1 illustrated in FIG. 16A, the foreign matter may be removed from the mounting area 110 by either or both of the processing gas and the brush 324. Also in the semiconductor manufacturing apparatus 1 illustrated in FIG. 16A, the connection between the transfer blade 11 and the transfer arm 12 may be fixed or attachable to or detachable from each other. The removal timing may be set based on the foreign matter information.

As described above, the semiconductor manufacturing apparatus 1 according to the fourth embodiment removes the foreign matter adhering to the mounting area 110 by physically rubbing the front surface of the mounting area 110. Others are substantially the same as those in the third embodiment, and duplicate description thereof is omitted.

### Modification

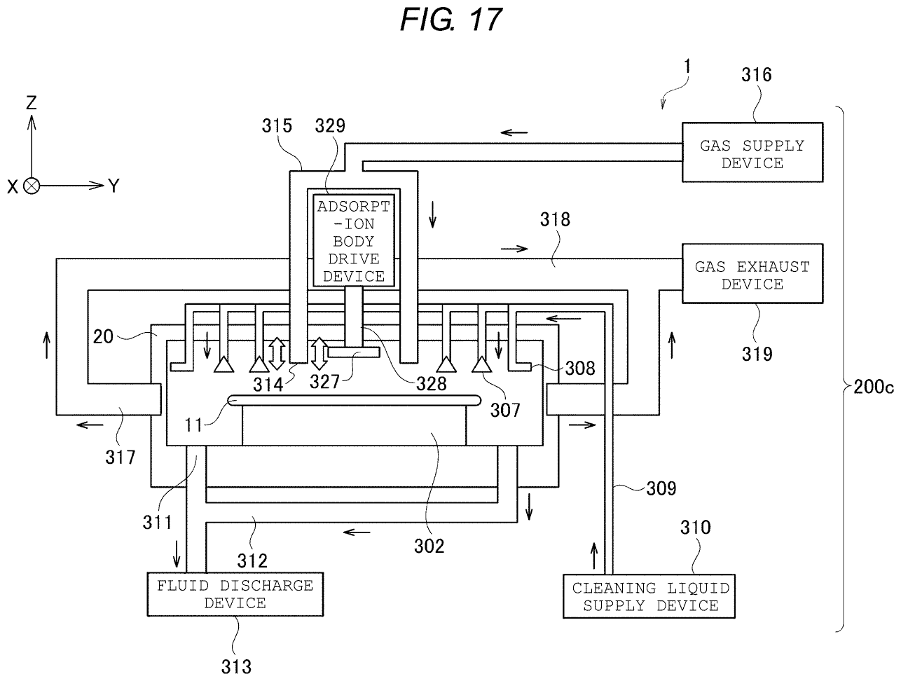

The semiconductor manufacturing apparatus 1 illustrated in FIG. 17 removes foreign matter adhering to the mounting area 110 by adsorbing the foreign matter adhering to the mounting area 110. FIG. 17 is a side view of the semiconductor manufacturing apparatus 1 when viewed from the transfer port side of the processing chamber 20. The semiconductor manufacturing apparatus 1 illustrated in FIG. 17 includes a removal apparatus 200c that adsorbs the foreign matter adhering to the mounting area 110. The removal apparatus 200c includes an adsorption body 327 that adsorbs foreign matter facing the front surface of the mounting area 110, an adsorption body drive unit 328 that drives the adsorption body 327, and an adsorption body drive device 329 that controls the adsorption body drive unit 328.

The semiconductor manufacturing apparatus 1 illustrated in FIG. 17 is different from the semiconductor manufacturing apparatus 1 illustrated in FIG. 16A in that the semiconductor manufacturing apparatus 1 illustrated in FIG. 17 includes the adsorption body 327, the adsorption body drive unit 328, and the adsorption body drive device 329 instead of the brush 324, the brush drive unit 325, and the brush drive device 326 of the removal apparatus 200b. The rest of configurations of the semiconductor manufacturing apparatus 1 illustrated in FIG. 17 are the same as those of the semiconductor manufacturing apparatus 1 illustrated in FIG. 16A.

The adsorption body 327 may be made of, for example, a material that adsorbs foreign matter. In that case, the adsorption body drive unit 328 drives the adsorption body 327 so that the adsorption body 327 comes into contact with the front surface of the mounting area 110 under the control of the adsorption body drive device 329. As such, the adsorption body 327 that adsorbs the foreign matter may be pressed against the front surface of the mounting area 110 to remove the foreign matter from the mounting area 110. Alternatively, the foreign matter may be adsorbed onto the adsorption body 327 by vacuum adsorption.

As illustrated by the double-headed arrow in FIG. 17, the adsorption body drive unit 328 may adjust the position of the adsorption body 327 along the Z-axis direction so that the adsorption body 327 comes into contact with or separates from the front surface of the mounting area 110. FIG. 17 illustrates a state in which the front surfaces of the adsorption body 327 and the mounting area 110 are separated from each other.

As described above, the foreign matter removal process may include a process of adsorbing the foreign matter on the front surface of the mounting area 110. In the semiconductor manufacturing apparatus 1 illustrated in FIG. 17, the foreign matter may be removed from the mounting area 110 by either or both of the processing gas and the adsorption body 327. Also in the semiconductor manufacturing apparatus 1 illustrated in FIG. 17, the connection between the transfer blade 11 and the transfer arm 12 may be fixed or may be a detachable connection. The removal timing may be set based on the foreign matter information.

The novel embodiments described herein may be embodied in a variety of other forms. For example, although the example in which the foreign matter removal process is automatically executed under the control of the control device 30 has been described above, the operator who operates the semiconductor manufacturing apparatus 1 may execute the foreign matter removal process.

In the above, the case where the upper surface of the pad 111 disposed in the mounting area 110 is the mounting area 110 of the transfer blade 11 has been described. However, the mounting area 110 is not limited to the upper surface of the pad 111. For example, the transfer blade 11 may not include the pad 111, and the upper surface of the transfer blade 11 may be the mounting area 110.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

### APPENDIX

### Appendix 1

A semiconductor manufacturing apparatus comprising:

a transfer device that includes a transfer blade whose mounting area on which a wafer is mounted is defined on a front surface, and a transfer arm connected to the transfer blade to adjust a position of the transfer blade; and

a processing chamber that accommodates the transfer blade and is for removing foreign matter adhering to the mounting area,

wherein the processing chamber includes a transfer port for carrying the transfer blade into the processing chamber and shutters for opening and closing the transfer port, and

the transfer port is closed by the shutters with the transfer arm interposed between the shutters, and the foreign matter adhering to the mounting area of the transfer blade accommodated in the processing chamber is removed with the shutters closed.

### Appendix 2

A semiconductor manufacturing apparatus comprising:

a transfer device that includes a transfer blade whose mounting area on which a wafer is mounted is defined on a front surface, and a transfer arm connected to the transfer blade to adjust a position of the transfer blade; and

a processing chamber that accommodates the transfer blade and is for removing foreign matter adhering to the mounting area,

wherein the transfer blade is connected so as to be attachable to and detachable from the transfer arm,
the processing chamber includes a transfer port for carrying the transfer blade into the processing chamber and shutters for opening and closing the transfer port, and
the transfer blade separated from the transfer arm is accommodated in the processing chamber, the shutters are closed with the transfer arm positioned outside the processing chamber, and the foreign matter adhering to the mounting area of the transfer blade accommodated in the processing chamber is removed with the shutters closed.

### Appendix 3

The semiconductor manufacturing apparatus according to appendix 1 or 2, wherein the foreign matter adhering to the mounting area is removed by plasma generated inside the processing chamber.

### Appendix 4

The semiconductor manufacturing apparatus according to any one of appendixes 1 to 3, wherein the processing chamber is also used as a chamber for performing wafer processing for forming a semiconductor device on the wafer.

### Appendix 5

A semiconductor manufacturing method comprising:

accommodating, at a predetermined removal timing, a transfer blade whose mounting area on which a wafer is mounted is defined on a front surface in a processing chamber; and

executing a foreign matter removal process of removing foreign matter adhering to the mounting area inside the processing chamber,

wherein the removal timing is set according to the number of times the wafer is mounted on the transfer blade immediately after a process of forming a film on a rear surface of the wafer.

### Appendix 6

A semiconductor manufacturing method comprising:

accommodating, at a predetermined removal timing, a transfer blade whose mounting area on which a wafer is mounted is defined on a front surface in a processing chamber; and

executing a foreign matter removal process of removing foreign matter adhering to the mounting area inside the processing chamber,

wherein the foreign matter removal process is executed every time a certain period of time elapses.

### Appendix 7

A semiconductor manufacturing method comprising:

acquiring foreign matter information indicating an adhering state of foreign matter on a mounting area on which a wafer is mounted;

accommodating a transfer blade whose mounting area is defined on a front surface in a processing chamber; and

executing a foreign matter removal process of removing the foreign matter adhering to the mounting area inside the processing chamber,

wherein, when the foreign matter information does not satisfy a predetermined determination condition, the transfer blade is accommodated in the processing chamber and the foreign matter removal process is executed.

### Appendix 8

The semiconductor manufacturing method according to any one of appendixes 5 to 7,

wherein, in the foreign matter removal process, plasma is generated inside the processing chamber to generate plasma, and the foreign matter is removed from the mounting area by exposing the mounting area to the plasma.

### Appendix 9

The semiconductor manufacturing method according to any one of appendixes 5 to 8, wherein the foreign matter removal process includes at least one of a process of cleaning the mounting area with liquid, a process of blowing gas onto the mounting area, a process of rubbing the mounting area with a brush, and a process of adsorbing the foreign matter on the mounting area.

What is claimed is:

1. A semiconductor manufacturing apparatus comprising:
a transfer device including:
a transfer blade having amounting area on which a wafer can be mounted, the mounting area being defined on a front surface of the transfer blade, and
a transfer arm connected to the transfer blade, and configured to adjust a position of the transfer blade; and
a processing chamber configured to accommodate the transfer blade and remove foreign matter adhering to the mounting area.

2. The semiconductor manufacturing apparatus according to claim 1, further comprising:
a controller configured to control the transfer device to accommodate the transfer blade in the processing chamber at a predetermined timing, and control a removal apparatus in the processing chamber to remove the foreign matter adhering to the mounting area at the predetermined timing.

3. The semiconductor manufacturing apparatus according to claim 1, wherein
the processing chamber includes:
a transfer port configured to carry the transfer blade into the processing chamber, and
at least one shutter configured to open and close the transfer port, and
wherein the removal of the foreign matter adhering to the mounting area of the transfer blade accommodated in the processing chamber is performed with the at least one shutter closed.

4. The semiconductor manufacturing apparatus according to claim 1, further comprising:
a foreign matter information acquisition apparatus configured to acquire foreign matter information indicating an adhering state of the foreign matter on the mounting area,
wherein, when the foreign matter information obtained by the foreign matter information acquisition apparatus does not satisfy a predetermined determination condition, the transfer blade is accommodated in the processing chamber and the foreign matter adhering to the mounting area is removed.

5. A semiconductor manufacturing method comprising:
accommodating at a predetermined timing, in a processing chamber, a transfer blade having amounting area on which a wafer is mounted, the mounting area being defined on a front surface of the transfer blade; and
executing a foreign matter removal process of removing foreign matter adhering to the mounting area inside the processing chamber.

6. The semiconductor manufacturing method according to claim 5,
wherein wafer processing for forming a semiconductor device on the wafer and the foreign matter removal process are performed in parallel.

7. The semiconductor manufacturing apparatus according to claim 1, wherein the transfer blade is attachable to and detachable from the transfer arm.

8. The semiconductor manufacturing apparatus according to claim 2, wherein the controller is configured to control the removal apparatus to remove the foreign matter adhering to the mounting area using plasma generated inside the processing chamber.

9. The semiconductor manufacturing method according to claim 5, wherein the predetermined timing is set according to the number of times the wafer is mounted on the transfer blade immediately after a process of forming a film on a rear surface of the wafer.

10. The semiconductor manufacturing method according to claim 5, wherein, in the foreign matter removal process, plasma is generated inside the processing chamber and the mounting area is exposed to the plasma.

11. The semiconductor manufacturing method according to claim 5, wherein the foreign matter removal process includes at least one of cleaning the mounting area with liquid, blowing gas onto the mounting area, rubbing the mounting area with a brush, or adsorbing the foreign matter on the mounting area.

12. The semiconductor manufacturing method according to claim 5, further comprising:
acquiring foreign matter information indicating an adhering state of foreign matter on the mounting area; and
wherein, when the foreign matter information does not satisfy a predetermined determination condition, the transfer blade is accommodated in the processing chamber and the foreign matter removal process is executed.

13. The semiconductor manufacturing method according to claim 5, wherein the foreign matter includes carbon.

14. The semiconductor manufacturing method according to claim 13, wherein the foreign matter removal process includes exposing the foreign matter to oxygen plasma.

15. The semiconductor manufacturing apparatus according to claim 7, including a clamp arranged to connect the transfer blade to the transfer arm.
